(19) United States
(12) Patent Application Publication
(10) Pub. No.: US 2015/0214394 A1
(43) Pub. Date: Jul. 30, 2015

(54) OPTO-ELECTRICAL CONVERSION STRUCTURE

(71) Applicant: AU OPTRONICS CORP., Hsinchu (TW)

(72) Inventors: Ming-Yi HUANG, HSIN-CHU (TW); Po-Chuan YANG, HSIN-CHU (TW); Jr-Hau HE, HSIN-CHU (TW); Hsin-Ping WANG, HSIN-CHU (TW); Tzu-Yin LIN, HSIN-CHU (TW)

(21) Appl. No.: 14/297,907

(22) Filed: Jun. 6, 2014

(30) Foreign Application Priority Data
Jan. 28, 2014 (CN) 201410041878.X

(51) Int. Cl. H01L 31/0236; H01L 31/068; H01L 31/075

(52) U.S. Cl. CPC H01L 31/02366; H01L 31/075; H01L 31/068

(57) ABSTRACT

An opto-electrical conversion structure includes a substrate, a first semiconductor structure, and a second semiconductor structure. The substrate has a first surface and a second surface opposite to each other. The first surface has a plurality of micro-structures and a plurality of nano-structures. The nano-structures are distributed on the surface of the micro-structures, and have heights of about 500 nm to about 900 nm. The first semiconductor structure is disposed on the first surface of the substrate. The second semiconductor structure is disposed on the second surface of the substrate.

### RELATED APPLICATIONS

This application claims priority to Chinese Application Serial Number 201410041878.X, filed Jan. 28, 2014, which is herein incorporated by reference.

### BACKGROUND

1. Field of Invention

The present invention relates to an opto-electrical conversion structure.

2. Description of Related Art

Human has growing demands for energy with the advance of technology. Since oil reserves have become shortage in view of the increasing energy requirements of the human, scientists and industry have greatly devoted themselves to the research and development of alternative energy. Among those, solar energy is one of the most desired new energies for the development.

A solar panel absorbs sunlight and converts solar energy of the sunlight into electrical energy. For enhancing the capturing amount of the sunlight, a plurality of micro-and/or nano-structures are generally formed on the incident surface of a solar cell of the solar panel to interfere with reflection on the incident surface of the solar cell. However, the surfaces of the nano-structures are formed so roughness that electron-hole recombination of the carriers generated from the solar cell is high, thereby adversely reducing the short-circuit current (Jsc) and the open-circuit voltage (V) of the solar cell.

### SUMMARY

An aspect of the present invention is to provide an opto-electrical conversion structure including a substrate, a first semiconductor structure, and a second semiconductor structure. The substrate has a first surface and a second surface opposite to each other. The first surface has a plurality of micro-structures and a plurality of nano-structures. The nano-structures are distributed on surfaces of the micro-structures, and heights of the nano-structures are about 500 nm to about 900 nm. The first semiconductor structure is disposed on the first surface of the substrate. The second semiconductor structure is disposed on the second surface of the substrate.

In one or more embodiments, each of the micro-structures is pyramid-shaped, recess-shaped, or combination thereof.

In one or more embodiments, a height of each of the micro-structures is about 1 μm to about 20 μm.

In one or more embodiments, the first semiconductor structure is an n-type semiconductor layer, and the second semiconductor structure is a p-type semiconductor layer; or the first semiconductor structure is a p-type semiconductor layer, and the second semiconductor structure is an n-type semiconductor layer.

In one or more embodiments, the first semiconductor structure includes an i-type semiconductor layer and a p-type semiconductor layer. The i-type semiconductor layer is disposed on the first surface of the substrate. The i-type semiconductor layer is disposed between the p-type semiconductor layer and the first surface of the substrate. The second semiconductor structure includes an i-type semiconductor layer and an n+-type semiconductor layer. The i-type semiconductor layer is disposed on the second surface of the substrate. The i-type semiconductor layer is disposed between the n+-type semiconductor layer and the second surface of the substrate.

Another aspect of the present invention is to provide a solar cell including the opto-electrical conversion structure, a first electrode structure, and a second electrode structure. The first semiconductor structure is disposed between the first electrode structure and the substrate. The second semiconductor structure is disposed between the second electrode structure and the substrate.

In one or more embodiments, the first electrode structure includes a transparent conductive layer and at least one metal electrode. The first semiconductor structure is disposed between the transparent conductive layer and the substrate. A portion of the transparent conductive layer is disposed between the metal electrode and the first semiconductor structure.

In one or more embodiments, the second electrode structure is a metal layer.

In one or more embodiments, the second electrode structure includes a transparent conductive layer and at least one metal electrode. The second semiconductor structure is disposed between the transparent conductive layer and the substrate. A portion of the transparent conductive layer is disposed between the metal electrode and the second semiconductor structure.

In one or more embodiments, the second surface of the substrate of the opto-electrical conversion structure has a plurality of micro-structures. The second electrode structure includes a transparent conductive layer and a metal electrode. The second semiconductor structure is disposed between the transparent conductive layer and the substrate. The metal electrode covers overall the transparent conductive layer.

Yet another aspect of the present invention is to provide a manufacturing method of an opto-electrical conversion structure including providing a substrate. A plurality of micro-structures are formed on a first surface of the substrate. The micro-structures are etched to form a plurality of nano-structures on surfaces of the micro-structures. The nano-structures are etched. A first semiconductor structure is formed on the first surface of the substrate. A second semiconductor structure is formed on a second surface of the substrate.

In one or more embodiments, etching the nano-structures includes etching the nano-structures to have heights of the nano-structures of about 500 nm to about 900 nm.

In one or more embodiments, the nano-structures are etched by performing an isotropic wet etching process.

In one or more embodiments, the nano-structures are etched by performing an anisotropic wet etching process.

In one or more embodiments, etching the micro-structures includes forming a plurality of catalysts on the surfaces of the micro-structures. The micro-structures are etched via the catalysts.

In one or more embodiments, etching the nano-structures includes removing the catalysts along with etching the nano-structures.

In one or more embodiments, the catalysts are metal nano-particles.

In one or more embodiments, the micro-structures are etched by performing an anisotropic wet etching process.

In one or more embodiments, forming the micro-structures includes forming a plurality of first micro-structures by performing an isotropic wet etching process.

In one or more embodiments, forming the micro-structures includes forming a plurality of second micro-structures on the first micro-structures by performing an anisotropic wet etching process.

### BRIEF DESCRIPTION OF THE DRAWINGS

FIGS. 1A to 1F are cross-sectional views of a method for manufacturing an opto-electrical conversion structure at different stages according to one embodiment of the present invention;

FIG. 2 is a cross-sectional view of a solar cell applying the opto-electrical conversion structure of FIG. 1F;

FIG. 3A is a cross-sectional view of a solar cell according to another embodiment of the present invention;

FIG. 3B is a cross-sectional view of a solar cell according to yet another embodiment of the present invention;

FIG. 4 is a V-I-curve graph of a solar cell according to one example of the present invention and its comparative examples;

FIG. 5 is an external quantum efficiency graph of the solar cell of FIG. 4 and its comparative examples; and

FIGS. 6A to 6G are cross-sectional views of a method for manufacturing an opto-electrical conversion structure at different stages according to another embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

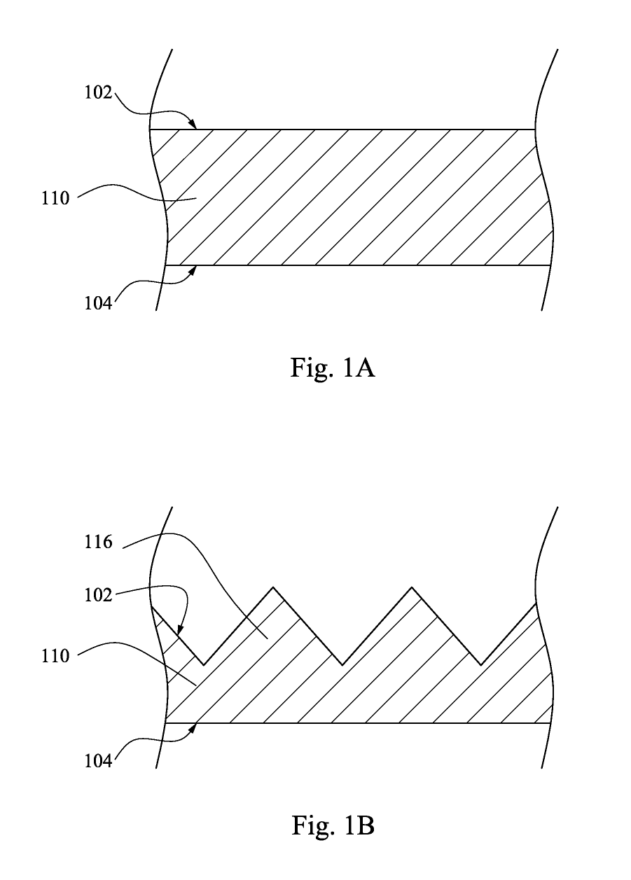

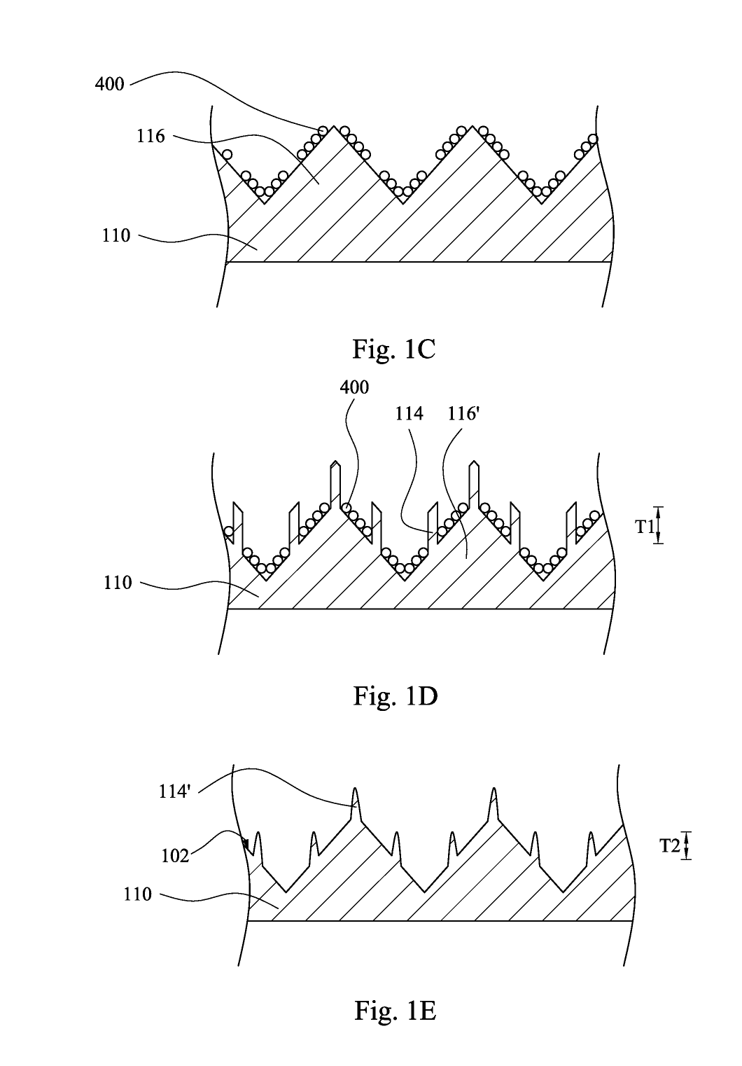

FIGS. 1A to 1F are cross-sectional views of a method for manufacturing an opto-electrical conversion structure at different stages according to one embodiment of the present invention. Reference is made to FIG. 1A. A substrate 110 is provided first. The substrate (or namely wafer) 110 has a first surface (or namely front surface) 102 and a second surface (or namely rear surface) 104 opposite to each other, and the substrate 110 can be made from semiconductor materials, such as a silicon (n-type monocrystalline silicon) substrate, and the claimed scope is not limited with this respect.

Reference is made to FIG. 1B, a plurality of micro-structures (or namely texture structures, or namely concave-convex structures) 116 are formed on the first surface 102 of the substrate 110. In this embodiment, the micro-structures 116 can be formed by performing an anisotropic wet etching process. For example, a mixed solution of alkaline solutions, such as KOH solution and isopropyl alcohol (IPA) solution, to be the etchant to form the micro-structures 116, and the micro-structures 116 are pyramid-shaped as shown in FIG. 1B.

Subsequently, the micro-structures 116 are further etched to form a plurality of nano-structures on the surfaces of the micro-structures 116. For example, reference is made to FIG. 1C, a plurality of catalysts can be formed on the surfaces of the micro-structures 116 first. The catalysts can be nano-particles 400 or a metal layer with nano-scale thickness. The nano-particles 400 are as an example in this embodiment. Reference is made to FIG. 1D. The micro-structures 116 are etched via the catalysts (i.e., the nano-particles 400) to form a plurality of nano-structures (or namely protrusion with nanometers-scale, or namely pillar with nanometers-scale, or namely column with nanometers-scale) 114 and micro-structures (or namely the etched micro-structures) 116′. In other words, the catalysts are disposed on portion of the micro-structures 116 and are exposed another portion of the micro-structures 116, the covered portion of the micro-structures 116 are etched by etchant via the catalysts, and the exposed another portion of the micro-structures 116 are not etched by etchant to form the protrusions. The nano-structures 114 are distributed on the micro-structures 116′. The nano-structures 114 formed in FIG. 1D can be nano-pillar structures with heights T1 about 2 μm.

In one or more embodiments, the catalysts may be made of metals, such as silver. The micro-structures 116 can be etched by performing an anisotropic wet etching process. Due to the anisotropic wet etching process, the etchant etches the micro-structures 116 downward via the catalysts (i.e., the nano-particles 400) to form a plurality of the nano-structures 114.

Reference is made to FIG. 1E. The nano-structures 114 are further etched to form nano-structures (or namely the etched nano-structures) 114′, such as the etched nano-structure has a tapered shape or tip shaped. The heights T1 of the nano-structures 114 are reduced to heights T2 which are about 500 nm to about 900 nm after the etching process. The etching process reduces the surface roughness of the nano-structures 114′, thus deceasing the carrier recombination of the substrate 110. Moreover, the nano-particles 400 (see FIG. 1D) originally disposed on the first surface 102 can be removed along with the nano-structures 114 etching process. In other words, this etching process reduces the surface roughness of the nano-structures 114 while altogether removes the nano-particles 400, thereby saving the manufacturing process.

In this embodiment, the nano-structures 114 can be etched by performing an isotropic wet etching process or an anisotropic wet etching process. For the isotropic wet etching process, a mixed solution of acid solutions, such as HF solution and HNO₃ solution, to be the etchant, and for the anisotropic wet etching process, a mixed solution of alkaline solutions, such as KOH solution and IPA solution, to be the etchant. However, it should be understood that the above-mentioned solutions are illustrative only and should not limit the scope of the claimed invention. A person having ordinary skill in the art may select suitable solutions according to actual requirements.

Reference is made to FIG. 1F. A first semiconductor structure 120 is formed on the nano-structures 114′ and the micro-structures 116′ of the first surface 102 of the substrate 110, and a second semiconductor structure 130 is formed on the second surface 104 of the substrate 110. The first semiconductor structure 120 and the second semiconductor structure 130 can be made from silicon, and can be formed by performing physical vapor deposition, such as sputtering process, or chemical vapor deposition.

Accordingly, the first surface 102 is anti-reflection due to the nano-structures 114′ and the micro-structures 116′ formed on the substrate 110 of the opto-electrical conversion structure 100 of this embodiment. In addition, after the nano-structures 114 are formed, the nano-structures 114 are further etched to form the nano-structures 114′ with the heights T2 in a range between about 500 nm and about 900 nm, thus the surface roughness of the nano-structures 114′ can be reduced to decrease the carrier recombination on the surface of the nano-structures 114′.

As a result, the manufacturing process of the opto-electrical conversion structure 100 is complete. From a structural point of view, the opto-electrical conversion structure 100 includes the substrate 110, the first semiconductor structure 120, and the second semiconductor structure 130. The substrate 110 has the first surface 102 and the second surface 104 opposite to each other. The first surface 102 has a plurality of the micro-structures 116′ and a plurality of the nano-structures 114′. The nano-structures 114′ are distributed on the micro-structures 116′, and heights T2 of the nano-structures 114′ are about 500 nm to about 900 nm. The first semiconductor structure 120 is disposed on the first surface 102 of the substrate 110. The second semiconductor structure 130 is disposed on the second surface 104 of the substrate 110.

In one or more embodiments, the first surface 102 can be a light incident surface of the opto-electrical conversion structure 100, and the second surface 104 can be a backlight surface of the opto-electrical conversion structure 100. However, in other embodiments, both of the first surface 102 and the second surface 104 can be the light incident surfaces of the opto-electrical conversion structure 100. That is, the opto-electrical conversion structure 100 is able to receive incident light from two ways, i.e. both surfaces of the opto-electrical conversion structure 100, and thus the second surface 104 may have the micro-structures 116′. Furthermore, the nano-structures 114′ can be disposed on the micro-structures 116′ of the second surface 104, and the claimed scope is not limited in this respect.

In this embodiment, the micro-structures 116′ can be pyramid-shaped, and heights T3 thereof can be about 1 μm to about 20 μm. Moreover, in this embodiment, the substrate 110 can be p-type semiconductor or n-type semiconductor, the first semiconductor structure 120 can be an n-type semiconductor layer, and the second semiconductor structure 130 can be a p-type semiconductor layer. Preferred, the substrate 110 is p-type semiconductor, the first semiconductor structure 120 is n-type semiconductor layer, and the second semiconductor structure 130 is p-type semiconductor layer, wherein doped concentration of the second semiconductor structure 130 is larger than doped concentration of the substrate 110. However, in other embodiments, the first semiconductor structure 120 can be a p-type semiconductor layer, and the second semiconductor structure 130 can be an n-type semiconductor layer, and the claimed scope is not limited in this respect. For example, the substrate 110 is n-type semiconductor, the first semiconductor structure 120 is p-type semiconductor layer, and the second semiconductor structure 130 is n-type semiconductor layer, wherein doped concentration of the second semiconductor structure 130 is larger than doped concentration of the substrate 110.

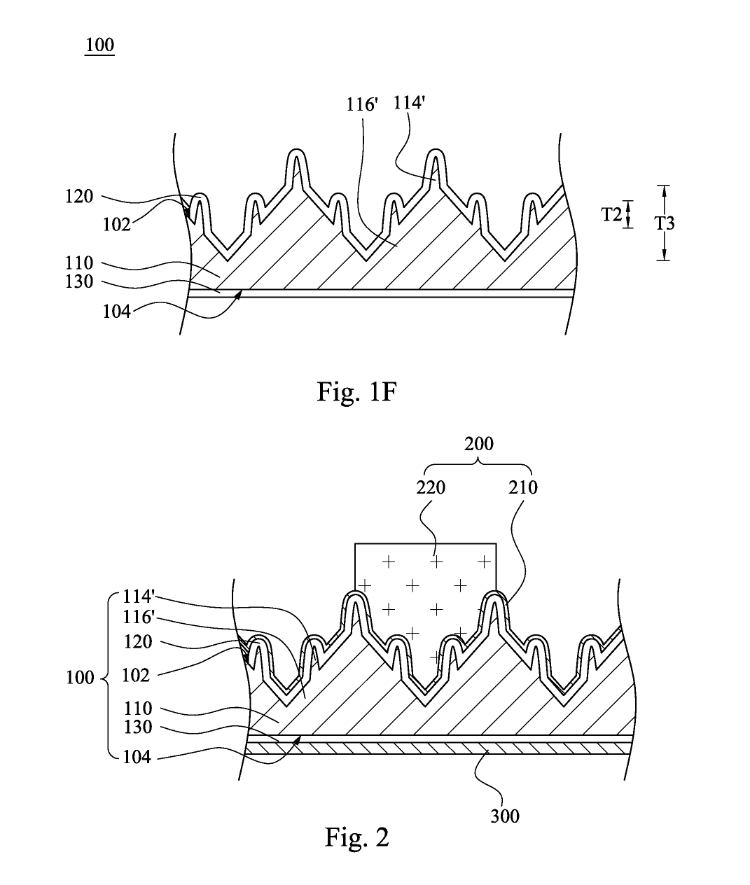

Reference is made to FIG. 2 which is a cross-sectional view of a solar cell applying the opto-electrical conversion structure 100 of FIG. 1F. In this embodiment, the solar cell includes the opto-electrical conversion structure 100 of FIG. 1F, a first electrode structure 200, and a second electrode structure 300. The first electrode structure 200 is formed on the surface of the first semiconductor structure 120, thus the first semiconductor structure 120 is disposed between the first electrode structure 200 and the substrate 110. The second electrode structure 300 is formed on the surface of the second semiconductor structure 130, thus the second semiconductor structure 130 is disposed between the second electrode structure 300 and the substrate 110.

Accordingly, sunlight can be incident solar cell from the surface of the first electrode structure 200. The opto-electrical conversion structure 100 converts sunlight into first charges and second charges, where the first charges can be electrons, and the second charges can be holes, or vise versa. The first charges can flow to the first electrode structure 200 from the first semiconductor structure 120, and the second charges can flow to the second electrode structure 300 from the second semiconductor structure 130.

In this embodiment, the first electrode structure 200 can include a transparent conductive layer 210 and at least one metal electrode 220. The transparent conductive layer 210 is formed on the surface of the first semiconductor structure 120, thus the first semiconductor structure 120 is disposed between the transparent conductive layer 210 and the substrate 110. The metal electrode 220 is formed on the surface of the transparent conductive layer 210, thus a portion of the transparent conductive layer 210 is disposed between the metal electrode 220 and the first semiconductor structure 120. The transparent conductive layer 210 can be made from tin doped indium oxide (ITO), tin oxide (SnO₂), zinc oxide (ZnO), aluminum doped zinc oxide (AZO), gallium doped zinc oxide (AZO), indium doped zinc oxide (IZO), or any combination thereof. The metal electrode 220 may be made from titanium, silver, aluminum, copper, or any combination thereof. Moreover, the second electrode structure 300 of the present embodiment can be a metal layer, which may be made from titanium, silver, aluminum, copper, or any combination thereof.

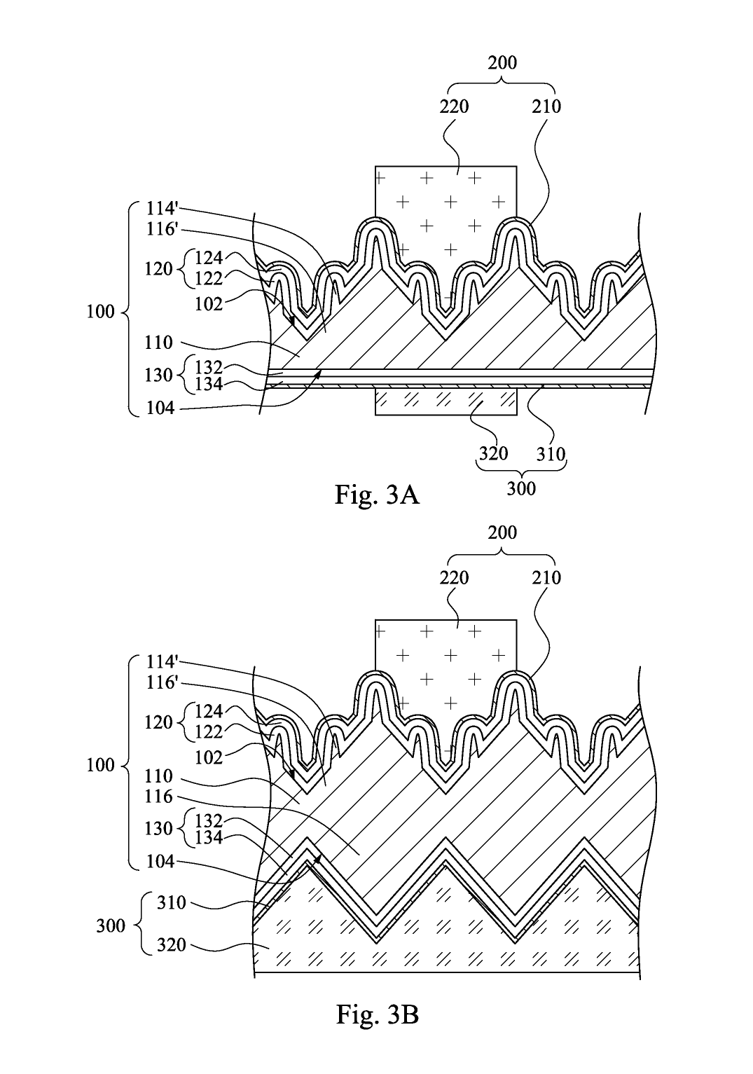

Reference is made to FIG. 3A which is a cross-sectional view of a solar cell according to another embodiment of the present invention. The difference between the present embodiment and the embodiment of FIG. 2 pertains to the configurations of the first semiconductor structure 120, the second semiconductor structure 130, and the second electrode structure 300. In this embodiment, the first semiconductor structure 120 includes an i-type semiconductor layer 122 and a p-type semiconductor layer 124. The i-type semiconductor layer 122 is disposed on the first surface 102 of the substrate 110, and is disposed between the p-type semiconductor layer 124 and the substrate 110. The second semiconductor structure 130 includes an i-type semiconductor layer 132 and an n+-type semiconductor layer 134. The i-type semiconductor layer 132 is disposed on the second surface 104 of the substrate 110, and is disposed between the n+-type semiconductor layer 134 and the substrate 110.

Accordingly, the sunlight can be incident the solar cell from the first electrode structure 200, and the opto-electrical conversion structure 100 can convert the sunlight into electrons and holes. The holes can sequentially pass through the i-type semiconductor layer 122 and the p-type semiconductor layer 124 to the first electrode structure 200. The electrons can sequentially pass through the i-type semiconductor layer 132 and the n+-type semiconductor layer 134 to the second electrode structure 300.

Moreover, the second electrode structure 300 of the present embodiment can include a transparent conductive layer 310 and at least one metal electrode 320. The transparent conductive layer 310 is formed on the surface of the second semiconductor structure 130, such that the second semiconductor structure 130 is disposed between the transparent conductive layer 310 and the substrate 110. The metal electrode 320 is formed on the surface of the transparent conductive layer 310, such that a portion of the transparent conductive layer 310 is disposed between the metal electrode 320 and the second semiconductor structure 130. Other relevant structural details of the present embodiment are all the same as the embodiment of FIG. 2, and, therefore, a description in this regard will not be repeated hereinafter.

Reference is made to FIG. 3B which is a cross-sectional view of a solar cell according to yet another embodiment of the present invention. The difference between the present embodiment and the embodiment of FIG. 3A is the structure of the second surface 104 of the substrate 100 and the metal electrode 320. In this embodiment, the second surface 104 has the micro-structures 116. That is, the second surface 104 of the substrate 100 is not limited to be flat. Moreover, in this embodiment, the metal electrode 320 covers overall the transparent conductive layer 310. For example, the metal electrode 320 can be formed on the transparent conductive layer 310 by performing sputtering process. Other relevant structural details of the present embodiment are all the same as the embodiment of FIG. 3A, and, therefore, a description in this regard will not be repeated hereinafter.

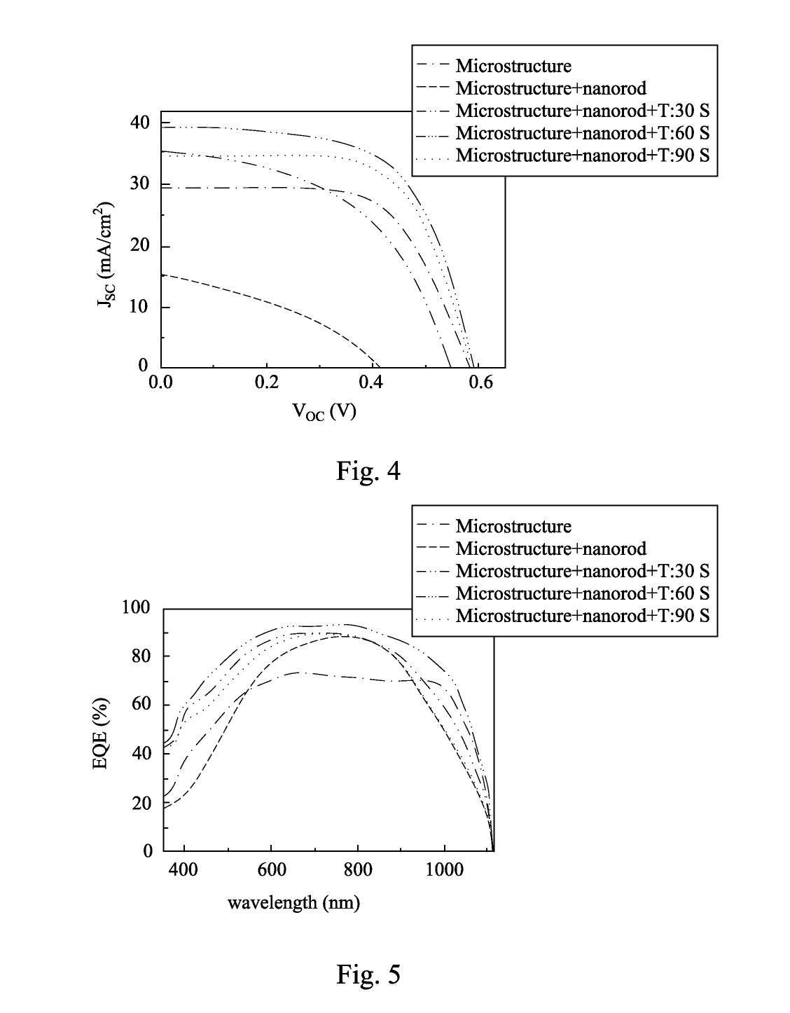

The following paragraphs provide simulation examples with respect to the efficiency of the solar cell mentioned above. FIG. 4 is a V-I-curve graph of a solar cell according to one example of the present invention and its comparative examples, and FIG. 5 is an external quantum efficiency graph of the solar cell of FIG. 4 and its comparative examples. The examples of FIGS. 4 and 5 were measured under 1 sun, atom mass (AM)=1.5, and sun illuminance=1000 W/m² using an Enlitech Quantum Efficiency apparatus. In this example, the structure of the solar cell is shown in FIG. 3B, and the manufacturing process of the opto-electric conversion structure 100 thereof are shown in FIGS. 1A to 1F. In greater detail, the substrate was made from n-type c-Si, whose thickness was about 160 μm. The surface of the substrate was anisotropic etched to form the pyramid-shaped micro-structures, where the etchant was a mixed solution of KOH solution and isopropyl alcohol (IPA) solution. Subsequently, 30 nm-thickness metal layer was sputtered on the micro-structures, and the substrate was disposed in a mixed solution of 1.632 ml HF solution, 0.436 ml H₂O₂ solution, and 7.932 ml D.I. water for 30 seconds and at room temperature to etch the micro-structures to form nano-structures on the surfaces of the micro-structures. Then, the nano-structures were isotropic etched, by which a mixed solution of 1:50 HF solution/HNO₃ for 30-90 seconds at 5° C. to etch the nano-structures, such that the heights of the nano-structures were etched to be about 500 nm to about 900 nm. The first semiconductor structure, the second semiconductor structure, the first electrode structure, and the second electrode structure were formed. The i-type semiconductor layer was made from i-a-Si:H, the p-type semiconductor layer was made from p-a-Si:H, the n+-type semiconductor layer was made from n-a-Si:H, the metal electrodes of the first electrode structure were made from silver, and the metal electrode of the second electrode structure was made of silver.

In FIG. 4, the short-circuit current (Jsc) and the open-circuit voltage (V) of the substrate with the micro-structures and the nano-structures were decreased, which indicates the carrier recombination was increased due to the roughness surfaces of the micro-structures and the nano-structures. However, after the nano-structures were etched, both of the short-circuit current and the open-circuit voltage of the substrate were increased no matter the etching period (or namely etching time) T was 30 seconds (30 S), 60 seconds (60 S), or 90 seconds (90 S), which proves the etching process of the nano-structures can smooth the surfaces of the micro-structures and the nano-structures.

Moreover, in FIG. 5, after the nano-structures were etched, the external quantum efficiency (EQE) of the substrate was increased no matter the etching period T was 30 seconds (30 S), 60 seconds (60 S), or 90 seconds (90 S), which represents the nano-structures still has anti-reflective function after the etching process of the nano-structures.

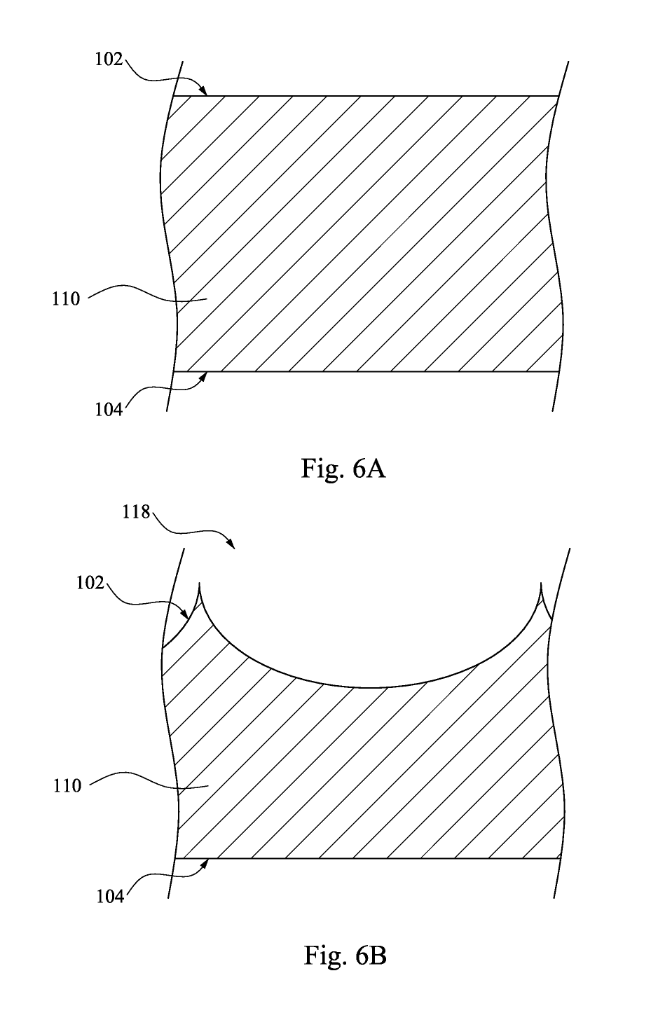

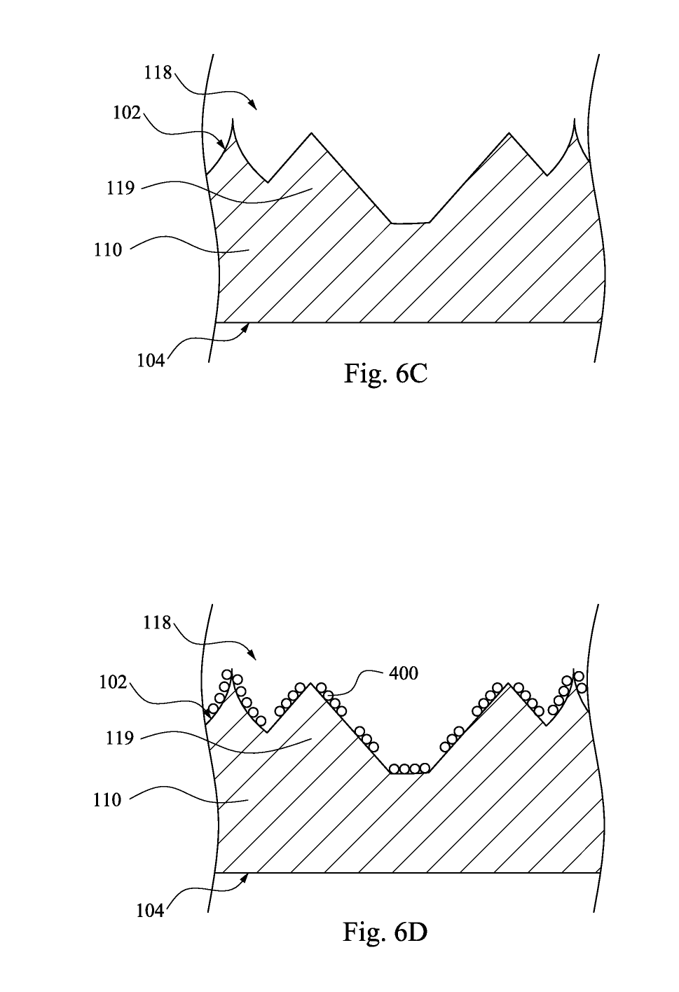

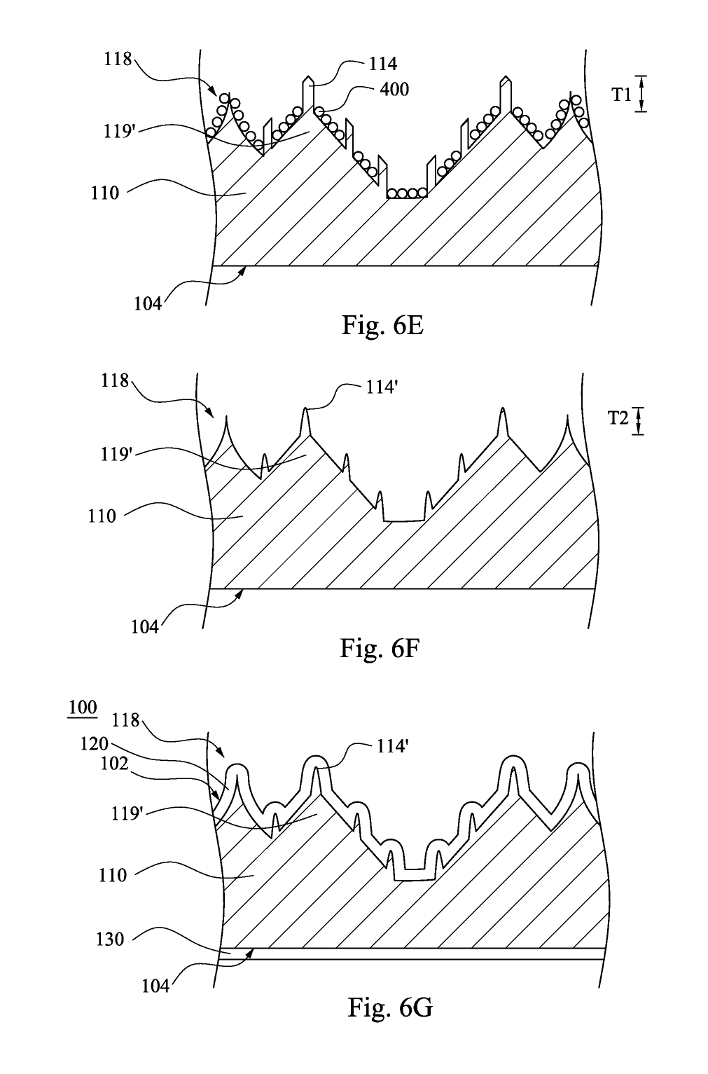

FIGS. 6A to 6G are cross-sectional views of a method for manufacturing an opto-electrical conversion structure at different stages according to another embodiment of the present invention. Reference is made to FIG. 6A. A substrate 110 with a first surface (or namely front surface) 102 and a second surface (or namely rear surface) 104 opposite to each other is provided. The substrate (or namely wafer) 110 can be made from semiconductor materials, such as silicon, and the claimed scope is not limited with this respect.

Reference is made to FIG. 6B. In another embodiment, a plurality of first micro-structures 118 are formed on the first surface 102 of the substrate 110, such as referring to FIG. 6B, the first micro-structures 118 has a convex having a tip shaped in cross-sectional view and a concave having a curved surface in cross-sectional view. In this embodiment, the first micro-structures 118 can be formed by performing an isotropic wet etching process. For example, a mixed solution of acid solutions, such as HF solution and HNO₃ solution, to be the etchant to form the first micro-structures 118, and the micro-structures 118 are recess-shaped as shown in FIG. 6B.

Reference is made to FIG. 6C. A plurality of second micro-structures 119 are formed on the first micro-structures 118 such as the second micro-structures 119 are formed on concave of the first micro-structures 118. In this embodiment, the second micro-structures 119 can be formed by performing an anisotropic wet etching process. For example, a mixed solution of alkaline solutions, such as KOH solution and IPA solution, to be the etchant to form the second micro-structures 119, and the second micro-structures 119 are pyramid-shaped as shown in FIG. 6C.

Subsequently, the second micro-structures 119 are further etched to form a plurality of nano-structures on the surfaces of the second micro-structures 119. For example, reference is made to FIG. 6D, a plurality of catalysts can be formed on the second micro-structures 119 first. The catalysts can be nano-particles 400 or a metal layer with nano-scale thickness. The nano-particles 400 are as an example in this embodiment. Reference is made to FIG. 6E. The second micro-structures 119 (see FIG. 6D) are etched via the catalysts (i.e., the nano-particles 400) to form a plurality of nano-structures (or namely protrusion with nanometers-scale, or namely pillar with nanometers-scale, or namely column with nanometers-scale) 114 and micro-structures 119′. In other words, the catalysts are disposed on portions of the second micro-structures 119′ and are exposed another portions of the second micro-structures 119′, the covered portion of the second micro-structures 119′ are etched by etchant via the catalysts, and the exposed another portion of the second micro-structures 119′ are not etched by etchant to form the protrusions. The nano-structures 114 are distributed on the micro-structures 119′. The nano-structures 114 formed in FIG. 6E can be nano-pillar structures with heights T1 about 2 μm.

In one or more embodiments, the catalysts may be made of metals, such as silver. The second micro-structures 119 can be etched by performing an anisotropic wet etching process. Due to the anisotropic wet etching process, the etchant etches the second micro-structures 119 downward via the nano-particles 400 to form a plurality of the nano-structures 114.

Reference is made to FIG. 6F. The nano-structures 114 are further etched to form nano-structures 114′ with heights T2 about 500 nm to about 900 nm. The surface roughness of the nano-structures 114′ can be reduced, thus deceasing the surface carrier recombination of the substrate 110. Moreover, the nano-particles 400 (see FIG. 6E) originally disposed on the first surface 102 can be removed along with the nano-structures 114 etching process. In other words, this etching process reduces the surface roughness of the nano-structures 114 while altogether removes the nano-particles 400, thereby saving the manufacturing process. In this embodiment, the nano-structures 114 can be etched by performing an isotropic wet etching process or an anisotropic wet etching process.

Reference is made to FIG. 6G. A first semiconductor structure 120 is formed on the nano-structures 114′ and the micro-structures 119′ of the first surface 102 of the substrate 110, and a second semiconductor structure 130 is formed on the second surface 104 of the substrate 110. The first semiconductor structure 120 and the second semiconductor structure 130 can be made from silicon, and can be formed by performing physical vapor deposition, such as sputtering process, or chemical vapor deposition. As a result, the manufacturing process of the opto-electrical conversion structure 100 is complete. Other relevant details of the present embodiment are all the same as the embodiment of FIG. 1F, and, therefore, a description in this regard will not be repeated hereinafter.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An opto-electrical conversion structure, comprising:
a substrate having a first surface and a second surface opposite to each other, wherein the first surface has a plurality of micro-structures and a plurality of nano-structures, wherein the nano-structures are distributed on surfaces of the micro-structures, and heights of the nano-structures are about 500 nm to about 900 nm;
a first semiconductor structure disposed on the first surface of the substrate; and
a second semiconductor structure disposed on the second surface of the substrate.

2. The opto-electrical conversion structure of claim 1, wherein each of the micro-structures is pyramid-shaped, recess-shaped, or combination thereof.

3. The opto-electrical conversion structure of claim 1, wherein a height of each of the micro-structures is about 1 μm to about 20 μm.

4. The opto-electrical conversion structure of claim 1, wherein the first semiconductor structure is an n-type semiconductor layer, and the second semiconductor structure is a p-type semiconductor layer; or the first semiconductor structure is a p-type semiconductor layer, and the second semiconductor structure is an n-type semiconductor layer.

5. The opto-electrical conversion structure of claim 1, wherein the first semiconductor structure comprises:
an i-type semiconductor layer disposed on the first surface of the substrate; and
a p-type semiconductor layer, the i-type semiconductor layer being disposed between the p-type semiconductor layer and the first surface of the substrate; and
wherein the second semiconductor structure comprises:
an i-type semiconductor layer disposed on the second surface of the substrate; and
an n+-type semiconductor layer, the i-type semiconductor layer being disposed between the n+-type semiconductor layer and the second surface of the substrate.

6. A solar cell, comprising:
an opto-electrical conversion structure, comprising:
a substrate having a first surface and a second surface opposite to each other, wherein the first surface has a plurality of micro-structures and a plurality of nano-structures, wherein the nano-structures are distributed on surfaces of the micro-structures, and heights of the nano-structures are about 500 nm to about 900 nm;
a first semiconductor structure disposed on the first surface of the substrate; and
a second semiconductor structure disposed on the second surface of the substrate;
a first electrode structure, the first semiconductor structure being disposed between the first electrode structure and the substrate; and
a second electrode structure, the second semiconductor structure being disposed between the second electrode structure and the substrate.

7. The solar cell of claim 6, wherein the first electrode structure comprises:
a transparent conductive layer, the first semiconductor structure being disposed between the transparent conductive layer and the substrate; and
at least one metal electrode, a portion of the transparent conductive layer being disposed between the metal electrode and the first semiconductor structure.

8. The solar cell of claim 6, wherein the second electrode structure is a metal layer.

9. The solar cell of claim 6, wherein the second electrode structure comprises:
a transparent conductive layer, the second semiconductor structure being disposed between the transparent conductive layer and the substrate; and
at least one metal electrode, a portion of the transparent conductive layer being disposed between the metal electrode and the second semiconductor structure.

10. The solar cell of claim 6, wherein the second surface of the substrate of the opto-electrical conversion structure has a plurality of micro-structures, and the second electrode structure comprises:
a transparent conductive layer, the second semiconductor structure being disposed between the transparent conductive layer and the substrate; and
a metal electrode covering overall the transparent conductive layer.

11. A manufacturing method of an opto-electrical conversion structure, comprising:
providing a substrate;
forming a plurality of micro-structures on a first surface of the substrate;
etching the micro-structures to form a plurality of nano-structures on surfaces of the micro-structures;
etching the nano-structures;
forming a first semiconductor structure on the first surface of the substrate; and
forming a second semiconductor structure on a second surface of the substrate.

12. The manufacturing method of claim 11, wherein etching the nano-structures comprises:
etching the nano-structures to have heights of the nano-structures of about 500 nm to about 900 nm.

13. The manufacturing method of claim 11, wherein the nano-structures are etched by performing an isotropic wet etching process.

14. The manufacturing method of claim 11, wherein the nano-structures are etched by performing an anisotropic wet etching process.

15. The manufacturing method of claim 11, wherein etching the micro-structures comprises:
forming a plurality of catalysts on the surfaces of the micro-structures; and
etching the micro-structures via the catalysts.

16. The manufacturing method of claim 15, wherein etching the nano-structures comprises:
removing the catalysts along with etching the nano-structures.

17. The manufacturing method of claim 15, wherein the catalysts are metal nano-particles.

18. The manufacturing method of claim 11, wherein the micro-structures are etched by performing an anisotropic wet etching process.

19. The manufacturing method of claim 11, wherein forming the micro-structures comprises forming a plurality of first micro-structures by performing an isotropic wet etching process.

20. The manufacturing method of claim 19, wherein forming the micro-structures comprises forming a plurality of second micro-structures on the first micro-structures by performing an anisotropic wet etching process.
